(19) United States
(12) Patent Application Publication
(10) Pub. No.: US 2023/0327452 A1
(43) Pub. Date: Oct. 12, 2023

(54) SWITCHING MATRIX FOR RECONFIGURABLE PV MODULES AND SYSTEMS

(71) Applicant: TECHNISCHE UNIVERSITEIT DELFT, Delft (NL)

(72) Inventors: Miroslav ZEMAN, Delft (NL); Olindo ISABELLA, Delft (NL); Andres CALCABRINI, Delft (NL); Vincenzo STORNELLI, Delft (NL); Mirco MUTTILLO, Delft (NL)

(73) Assignee: TECHNISCHE UNIVERSITEIT DELFT, Delft (NL)

(21) Appl. No.: 17/995,627

(22) PCT Filed: Mar. 25, 2021
(86) PCT No.: PCT/NL2021/050199

§ 371 Date: Oct. 6, 2022

(30) Foreign Application Priority Data
Apr. 7, 2020 (NL) 2025292

(51) Int. Cl. H02J 3/38

(52) U.S. Cl. CPC H02J 3/38; H02S 40/34

(57) ABSTRACT

The present invention is in the field of a switching matrix for reconfigurable PV modules and systems, in order to compensate for sub-optimal functioning cells, such as due to shading, by automatically interconnecting cells and/or blocks to optimize output power of a PV-module or modules or systems.

### FIELD OF THE INVENTION

The present invention is in the field of a switching matrix for reconfigurable PV modules and systems, in order to compensate for sub-optimal functioning cells, such as due to shading, by automatically interconnecting cells and/or blocks to optimize output power of a PV-module or modules or systems.

### BACKGROUND OF THE INVENTION

In the field of energy conversion PV-systems are known. These systems generally use at least one PN-junction to convert solar energy to electricity.

A disadvantage of such a system is that the conversion per se is not very efficient, typically, for Si-solar cells, limited to some 25%. Even using very advanced PV-cells, such as GaAs cells, the conversion is only about 30%. Inherently these systems are limited in their conversion.

Further these systems are still relative expensive to manufacture.

Systems are typically not optimized in terms of energy production, use of energy, availability of energy, etc., especially in view of consumption patterns of a building. Integration with for instance other household applications is otherwise typically not provided.

Integration of systems is typically also in its initial stage. Not many applications are available yet.

So existing PV systems show huge power output losses, and significant quantities of generated power are not usable because of e.g. too low power at low light conditions, due to dirty cells, sub-optimal performance of certain cells, and shading, effecting the total output of a PV-module. Using a micro inverter or the like does not solve this problem.

Especially shading causes a huge power loss in a PV system and it is typically not proportional to the shaded area. Besides, it also causes hot-spots on PV cells and ages the PV module faster. Partial shading is a very common problematic that affects a large number of photovoltaic systems in the urban environment. Partial shading can be caused by trees, buildings, chimneys, dormers or any other object that can cast a shadow on the surface of a solar panel. Solar cell in conventional photovoltaic modules have a fixed interconnection which maximizes the electrical performance under uniform irradiance conditions. When a module is partially shaded, the irradiance on the surface of the PV module is not uniform. Modules that are designed to operate most of the time under uniform illumination perform very poorly under non-uniform illumination. This is because most of the solar cells in a module are connected in series. When a solar cell is less illuminated, it generates less electrical power and a lower electrical current, which in turn reduces the output power of the more illuminated cells connected in series to it. If solar cells are interconnected in parallel (instead of in series), the performance of a shaded cell almost does not affect the output power of unshaded cells, and hence the electrical output power of the photovoltaic module is much less sensitive to partial shading. However, under uniform illumination conditions, a solar panel that has many solar cells are connected in parallel delivers high current which creates large resistive losses in the interconnections, the wires and the power electronic devices. As a result, under uniform illumination conditions, it is more convenient to use a solar module with solar cells connected in series, while under partial shading conditions, it is more convenient to use a solar module with solar cells connected in parallel. Bypass diodes may be used in commercial PV modules to reduce effects of hot spots or shading on a PV module. Bypassing elements comprise different types of passive semiconductor-based devices which are connected in parallel to groups of solar cells. When solar cells are partially shaded, the diodes offer an alternative path to the excess of current generated by the more illuminated cells. Commercial modules usually include 3 bypass elements which are generally connected to groups of 20 or 24 solar cells. Recently, the active bypass technology has been developed to reduce hotspot even more and provide higher efficiency. In an alternative to bypassing, groups of solar cells are interconnected forming both series and parallel connections. The interconnections between cells are fixed and cannot be changed. One commercially available example of this are half-cell solar modules, such as REC Alpha series modules. However, for these techniques still a considerable amount of PV module power is lost when a small area of shade is present (⅓ of the PV module power or even more).

Some prior art documents recite smart photovoltaic cells and modules, such as US 2011/073150 A1, WO 2017/048597 A1, and WO 2014/169295 A1. US 2011/073150 A1 recites diode-less terrestrial photovoltaic solar power arrays, i.e. without blocking diodes and/or without bypass diodes. The arrays may comprise a solar array tracker, a controller, and an inverter. When the controller senses that the solar module power is below a threshold level, the controller commands the solar tracker to vary the solar module's pointing until the solar module is operating at its maximum power point for the solar module's level of illumination. In some embodiments, when the controller senses that the solar module power is less than a minimum bypass threshold level, the controller commands a bi-position switch to bypass current around the solar module. WO 2017/048597 A1 recites de-energizing a photovoltaic (PV) system, which may include detecting a resistance between a first photovoltaic unit and ground, wherein the first photovoltaic unit is connected to at least one additional photovoltaic unit. If the resistance is less than a threshold, the first photovoltaic unit is shorted by connecting a positive conductor of the first photovoltaic unit with a negative conductor of the first photovoltaic unit. Shorting the first photovoltaic unit causes the at least one additional photovoltaic unit to detect the resistance that is less than the threshold, thereby shorting the at least one additional photovoltaic unit by connecting a positive conductor of the at least one additional photovoltaic unit with a negative conductor of the at least one additional photovoltaic unit. WO 2014/169295 A1 recites a solar photovoltaic module laminate for electric power generation. A plurality of solar cells is embedded within module laminate and arranged to form at least one string of electrically interconnected solar cells within said module laminate. A plurality of power optimizers is embedded within the module laminate and electrically interconnected to and powered with the plurality of solar cells. Each of the distributed power optimizers capable of operating in either pass-through mode without local maximum- power-point tracking (MPPT) or switching mode with local maximum-power- point tracking (MPPT) and having at least one associated bypass switch for distributed shade management.

WO 2019/143242 A1 recites a cell-level power managed PV-module, and a method of operating said module, such as operating a large number of PV-modules, such as in a solar farm. Typically a multitude of individual PV-cells is present at a front side of the module that need to be operated and controlled.

The present invention therefore relates to an improved cell-level power managed PV-module, and a method of operating such a module, which solve one or more of the above problems and drawbacks of the prior art, providing reliable results, without jeopardizing functionality and advantages.

### SUMMARY OF THE INVENTION

The present invention relates to a cell-level power managed PV-module comprising a multitude of individual PV-cells (i,j) located at a front side of the module, in an array of n*m cells, i∈[2;n], and j∈[2;m], a junction box (10) comprising a switch driver circuit (11) adapted to provide individual input to and driving a switching matrix (12), the switching matrix adapted to electrically reconnect at least one PV-cell (13), preferably reconnect blocks of PV-cell, wherein each block comprises at least one PV-cell, and adapted to receive input from the at least one PV-cells, at least one sensor (14) per block of PV-cells adapted to receive input from the at least one PV-cell (13), optionally a self-start circuit (15), a power management circuit (16) adapted to receive input from the at least one PV-cell and/or optional self-start circuit (15), a power converter (18), preferably a power converter with maximum power point tracking (MPPT) adapted to provide input to the power management circuit, adapted to provide load, and adapted to receive input from the at least one PV-cell, a main processing unit (17), such as a microcontroller, the main processing unit adapted to receive input from sensors, adapted to receive input from the power management circuit, adapted to provide input to the switch driver circuit, adapted to provide input to the power management circuit, and adapted to provide input to the power converter. The present invention relates to an electronic circuit capable of changing the electrical connections between “reconfigurable blocks”, which are groups of series-connected photovoltaic solar cells. The electrical power that can be extracted from a PV module may depend on the interconnection between the reconfigurable blocks and on the shading profile on the surface of the solar panel. The present invention is adapted to automatically recognize the shading profile on the solar panel's surface and then choose the best interconnection of reconfigurable blocks to maximize the output power of the solar panel. The block diagram of FIG. 1 shows main system components. Sensors may be used to identify which cells of the PV modules are shaded, such as current sensors and/or irradiance sensors. From the sensor measurements, such as current measurement, an algorithm implemented in the main processing unit determines which of all the possible configurations of the PV module offers the highest output power. Partial implementations of the switching matrix may also be possible. For example, the matrix in FIG. 2 has 25 switches and it allows the module to adopt 27 electrically different configurations. For example: the 6 blocks of cells in the figure can be all in parallel by closing switches 12b and 12a and opening all the switches 12c, or all in series by closing switches 12c and opening switches 12a and 12b, or in 25 different series-parallel configurations with other combinations of opened and closed switches. However, it is not required for a reconfigurable module with 6 blocks of cells to be able adopt all the 27 electrical configurations. To make the design of the switching matrix simpler, cheaper or more reliable, we might decide to include less switches and hence the module won't be able to adopt all the 27 configurations. The switch driver circuit conditions the signals generated by the main processing unit to control which of the switches in the switching matrix must be opened or closed. The positive and negative terminals of the photovoltaic module are connected to a power converter (either DC-DC or DC-AC) that extracts the maximum power out of the selected module configuration. The system may include a self-start circuit, which allows it to start up the main processing unit using the power extracted from the reconfigurable blocks. Once the processing unit is operative, the maximum power point tracking algorithm (MPPT) in the power converter starts extracting power from the module. This converter can be used to power an external load and to supply power to the internal circuit. The present junction box provides e.g. a reconfigurable PV module, a shade tolerant PV module, and a dynamic reconfigurable switching matrix. The present design of the switching matrix allows to minimize conduction losses and the number of required components. The present solution is not restricted to two reconfigurable blocks, it is scalable. No bypass diodes are required to protect the reconfigurable blocks of cells. The way in which switches and reconfigurable blocks are connected with each other is considered a further improvement. An improved design of the switch driving circuit that is needed to condition the signals to open and close the switches is provided. And it may comprise a self-starting circuit, which eliminates the need for external power sources to power up the invention. It allows to maximize the power extracted from partially shaded photovoltaic systems. It is found that a partially shaded PV system which integrates the present solution produces up to 20% more electrical energy per year than the most shade tolerant solution that can be found today in the market (i.e. half-cell PV modules with module level power optimizers). This is achieved by the present hardware and the developed algorithm that can estimate the shape of the shadow on the surface of the photovoltaic module without the need to do a full tracing of the current-voltage characteristics of the photovoltaic module. When the most shaded groups of solar cells are identified, the logic implemented in the processing unit of the board determines which is the best way to electrically connect the groups of cells with each other.

The present module comprises at least one switch per block of PV-cells for reconnecting or disconnecting said block of PV-cells at a positive side of the block of cells and at least one switch at a negative side of the block of cells(see e.g. FIG. 2).

The present module in a row of n PV-cells each PV-cell ∈[1,n−1] comprises one first switch (12a) at either a positive or negative side of a PV-cell, each first switch connecting or disconnecting to a positive or negative load respectively, and in a row of n PV-cells each PV-cell ∈[2,n] comprises n second switches (12b,c) at the other side of a PV-cell, each second switch (12b) either connecting or disconnecting to the other load respectively, or each second switch (12c) connecting or disconnecting to an opposite side of an n-1^{th} to 1^{st} PV-cell respectively.

The present solution allows to increase the electrical power output of a solar panel under partial shading conditions. The present solution can be added to existing photovoltaic systems to increase their yield. It allows to identify the illumination conditions on the surface of the solar panel using sensors and the to change the connection between solar cells using a switching matrix. If the module is uniformly illuminated, the module will have more series connections, while if it is partially shaded it will have more parallel connections. Additionally, the solution can be self-powered with the solar cells in the solar panel eliminating the need for batteries or an external power supply. However, the power needed by the processing unit could also be drawn from a battery or an external electrical source.

The module may comprise a multitude of PV-cells (i,j), typically a physical array of n*m cells, i∈[1;n], and j∈[1;m], wherein n may be from 2-2¹⁰, preferably 3-2⁸, more preferably 4-2⁶, even more preferably 5-2⁵, such as 6-2⁴, and wherein m may be from 2-2¹⁰, preferably 3-2⁸, more preferably 4-2⁶, even more preferably 5-2⁵, such as 6-2⁴. The PV-cells may be located at a front side of the module, typically facing the sun. Contrary to prior art PV-modules the present cells may be operated individually, and combinations of electrically connected cells, in parallel, in series, or a combination thereof, are established based on operational characteristics of individual cells. The electrical operation topology is most likely very different from a physical topology with the array of n*m cells. For instance, an arbitrary example cell n=1 m=1 may be connected to a further arbitrary cell n=21 m=8; such a connection is without the present invention at least physically complex or impossible. Thereto, in the present module each individual cell is individually connected by electrical connections to a junction box and controlled by a switching network. The switching network is aimed at providing an electrically based order. The switching network comprises a plurality of switchable elements for opening or closing electrical connections, a processor for actively controlling the switchable elements, such as by opening and closing these, a current and/or irradiance sensor per cell, the switching network forming at least one string of PV-cells by electrically connecting k PV-cells, typically a memory, and a plurality of switches and may comprise a wireless transceiver. Based on operational characteristics of individual cells these cells are mutually connected in parallel, in series, or a combination thereof, or are left out, such that an optimal power output is achieved. Typically the connections are continuously re-evaluated in terms of power output, and an electrical configuration of PV-cells and the junction box is provided when in operation; this configuration therefore comprises active and contributing PV-cells, electrical connections from the cells to the junction box, the switched network in the junction box, and leaves out underperforming or inactive PV-cells. Connection may be established or switched off at a frequency of 0.1 Hz-1 MHz, and typically at a rate above 40 kHz.

The present switch may be controlled by a MOSFET or bipolar transistor, which may be of NPN or PNP type. The switching network provides a response based on input provided by the sensors, and optionally by temperature sensors. At a sensing step recorded data from the memory may be compared with a previous set of data, such as for establishing a working condition (e.g. in terms of voltage and current) of all individual cells. The (micro-)processor can than switch the network such that a maximum output is obtained. In addition, the processor can evaluate safety issues, such as by identifying to hot cells, and shorts.

Various possible scenarios of operation may occur. In a first scenario the same or almost the same current is measured by all the current sensors. In such a case all cells are considered to be in operation under uniform irradiation and the cells have compared to an average c.q. to one and another a minor mismatch. Any electrical configuration is now possible and typically all the strings of cells may be connected in series to minimize Joule losses. In a second scenario one sensor measures a current slightly different (e.g. 1%-2%) from all of the rest. There seems to be no need for immediate action and switch-states are not modified. It may be assumed that to the small current difference corresponding cells are sub-optimally functioning, such as caused by dust, cracking, ageing, an inherent mis-match, or a combination thereof. The cause may be determined based on a time duration of the situation. At regular intervals the control circuit (or controller, or processor) can decide whether it is better to change the active switch configuration, or not. Eventually an alarm may be generated and sent to an operator, such that a visual inspection of the module may be performed. In a third scenario a significantly lower amount of current, such as 5%-100%, passes through at least one current sensor. The to the lower current corresponding cells may be shaded significantly or damaged seriously, which now may force the controller to change the state of the switches, such as favouring module configurations with more parallel connections. Based on a measured output power, and optionally a temperature, the control circuit may decide whether to keep the corresponding configuration or to switch to a different one, which may be determined on a maximum power or on safety requirements.

Various circuit topologies may be envisaged. A first circuit topology optimises efficiency and has a low chance of hot spots, a second circuit topology slightly optimises efficiency and has a low chance of hot spots, a third circuit topology optimises efficiency and has a high chance of hot spots, and a fourth circuit topology slightly optimises efficiency and has a high chance of hot spots. Different module topologies might be envisaged. The amount of reconfigurable groups, the amount of cells per reconfigurable groups, the size of the solar cells and the position of the solar cells in the PV module may be chosen to increase the shade resilience of the PV module, to reduce conduction losses, etc. As such the invention provides for a variety in possible circuits.

To minimize shading losses and to reduce their negative effects, the present cell-level power management system is developed to control each cells performance at shading condition which may also to communicate with an operator. A smart cell-level power managed PV module may contain a printed circuit board inside its junction box while reconfigurable (groups of) PV cells of the modules are typically connected to this box through a back-sheet routing system. This smart PV module can understand the working condition of its cells and manage them to obtain a highest available power. It may also provide communication signals containing information about working condition PV cells for the user. Therefore, more energy will be saved during shading and a PV system user may also be notified about the working condition of every individual cell within the PV system. The ability to decide when and which bypass elements should be turned on or off to obtain a maximum possible power is novel. So obtained results are a higher efficiency, a longer life-time, improved grid stability, and more reliability for Smart cell-level power managed PV module in comparison with current commercially available PV modules, and therefore a lower cost of ownership.

The present switching network with many bypass elements is controlled by a (micro-)processor to make the module intelligent and robust against non-uniform irradiation conditions. The processor is adapted, such as by programming, to give the module the ability to detect its own working condition, select the best circuit topology for that specific working condition, and also providing information for a PV system user through a communication circuit and monitoring system.

In a second aspect the present invention relates to a method of operating a PV-module comprising n*m cells, and a switching network comprising a plurality of switches, a processor for controlling the switches, a sensor per cell, wherein each PV-cell is individually connected by electrical connections to and controlled by the switching network, comprising receiving for at least two cells sensor output per cell, and connecting or disconnecting switches.

In a third aspect the present invention relates to a junction box (10) comprising a switch driver circuit (11) adapted to provide individual input to and driving a switching matrix (12), the switching matrix adapted to electrically reconnect at least one PV-cell (13), preferably reconnect blocks of PV-cell, wherein each block comprises at least one PV-cell, and adapted to receive input from the at least one PV-cells, at least one sensor (14) per block of PV-cells adapted to receive input from the at least one PV-cell (13), optionally a self-start circuit (15), a power management circuit (16) adapted to receive input from the at least one PV-cell and/or optional self-start circuit (15), a power converter (18), preferably a power converter with maximum power point tracking (MPPT) adapted to provide input to the power management circuit, adapted to provide load, and adapted to receive input from the at least one PV-cell, a main processing unit (17), such as a microcontroller, the main processing unit adapted to receive input from sensors, adapted to receive input from the power management circuit, adapted to provide input to the switch driver circuit, adapted to provide input to the power management circuit, and adapted to provide input to the power converter, comprising at least one switch per block of PV-cells for reconnecting or disconnecting said block of PV-cells at a positive side of the block of cells and at least one switch at a negative side of the block of cells.

In a fourth aspect the present invention relates to a computer program comprising instructions, the instructions causing the computer to carry out the following steps: receiving input from at least one sensor (14), receiving input from the power management circuit (16), providing input to the switch driver circuit (11), providing input to the power management circuit (16), and providing input to the power converter (18).

As identified throughout the description the present module and likewise the present method may comprise further elements or details, as provided throughout the description, and in particular in the claims.

Thereby the present invention provides a solution to one or more of the above-mentioned problems and drawbacks.

Advantages of the present description are detailed throughout the description.

### DETAILED DESCRIPTION OF THE INVENTION

The present invention relates in a first aspect to a module according to claim 1.

In an exemplary embodiment of the present module the switching matrix may comprise electrically controllable switches, such as controllable by a transistor, such as a MOSFET, such as an N-channel MOSFET or p-channel MOSFET, or an NPN or PNP bipolar junction transistor, e.g. in electrical connection a transistor and a diode as a bidirectional half control switch.

In an exemplary embodiment the present module may comprise at least one switch per block of cells for reconnecting or disconnecting said block of cells.

In an exemplary embodiment the present module may comprise at least one switch per block of PV-cells for reconnecting or disconnecting said block of PV-cells at a positive side of the block of cells and at least one switch at a negative side of the block of cellsat each cell, apart from a first cell in a block (see e.g. FIG. 2).

In an exemplary embodiment the present module may comprise at least one sensor (14) per PV-cell.

In an exemplary embodiment of the present module the PV-cell may be selected from conventional homo-junction and heterojunction solar cells, mono-facial and bi-facial solar cells, n-type and p-type mono-crystalline Si, micro-crystalline Si bulk, front contacted solar cells, back contacted solar cells, front and rear junction solar cells, and interdigitated back contacted solar cells, and combinations thereof.

In an exemplary embodiment of the present module the junction box may be located at a back side of the module and may preferably be centrally placed.

In an exemplary embodiment of the present module the junction box may be an integrated circuit or PCB.

In an exemplary embodiment of the present module the junction box may be located on a back of the PV-module, on the edge of the PV-module, or incorporated in the PV-module, such as inside the lamination (e.g. in between the glass sheet).

In an exemplary embodiment of the present module the junction box may comprise a printed circuit board provided with a power circuit.

In an exemplary embodiment of the present module the main processing unit may comprise at least one of a clock, a ground, a Vcc, an AD current, an AD-voltage, and a temperature sensor.

In an exemplary embodiment the present module may comprise a communication circuit.

In an exemplary embodiment the present module may comprise embedded software for operating the module, and optionally comprising an alarm.

The present module may be used in a photo-voltaic system, wherein the system is preferably selected from building integrated photovoltaics, vehicle integrated photovoltaics, and urban photovoltaic systems.

In an exemplary embodiment the present method a cell temperature may be measured. In an exemplary embodiment the present method an output power of at least two cells may be measured.

In an exemplary embodiment the present method 26-220 PV modules may be maintained and operated.

In an exemplary embodiment of the present module electrical connections of each individual cell (i,j) may have a thickness of <0.1 mm, a width of <10 mm, and a length of <200 cm, and optionally a doping of 1*10¹⁷/cm³-5*10¹⁹/cm³, preferably such that power losses are minimal.

In an exemplary embodiment the present module may comprise at least one power provider selected from a battery, a battery charger, and a voltage regulator.

The one or more of the above examples and embodiments may be combined, falling within the scope of the invention.

### EXAMPLES

The below relates to examples, which are not limiting in nature.

The invention is further detailed by the accompanying figures, which are exemplary and explanatory of nature and are not limiting the scope of the invention. To the person skilled in the art it may be clear that many variants, being obvious or not, may be conceivable falling within the scope of protection, defined by the present claims.

### FIGURES

The invention although described in detailed explanatory context may be best understood in conjunction with the accompanying figures.

FIGS. 1-2 show schematics of a topology of the present junction box 10 and connections established therewith.

FIGS. 3a-b show a comparison between a prior art layout and the present layout.

### DETAILED DESCRIPTION OF THE FIGURES

In the figures:
10 Junction box
11 switch driver circuit
12 switching matrix
12a first switch
12b second switch opposite of first switch
12c second switch connecting to lower ranked PV-cell
13 reconfigurable PV-blocks
14 current sensors
15 Self-start circuit
16 Power management circuit
17 Main processing unit
18 Power converter with MPPT
19 Load

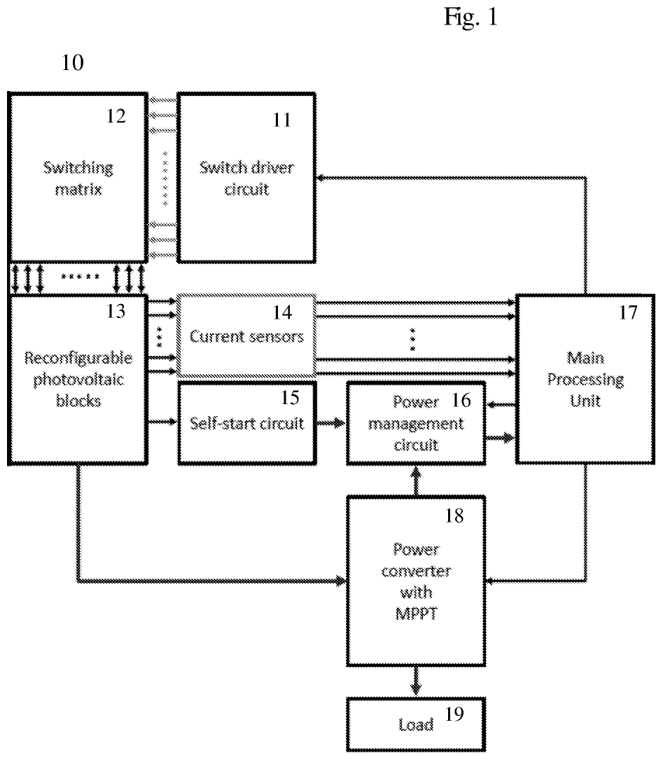

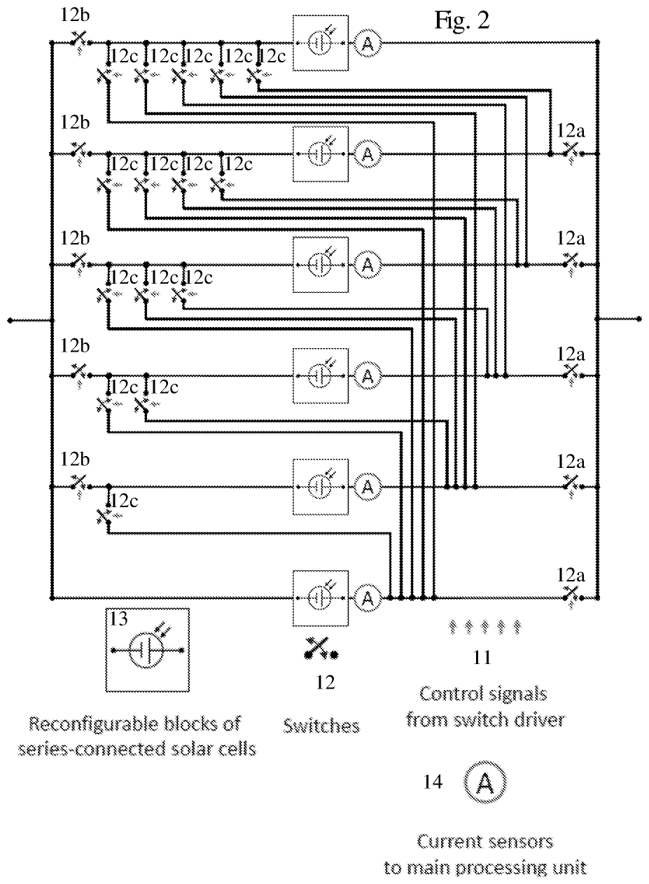

In FIG. 1, the reconfigurable photovoltaic blocks (13) consists of a number of cells connected in series (at least two). The number of reconfigurable blocks in a PV module and the number of solar cells in each reconfigurable block can vary from one implementation to another. Each reconfigurable group is electrically connected in series with a current sensor (14) and to the switching matrix (12) as shown in FIG. 2. To control the switches, the main processing unit generates as many signals as switches in the switching matrix. This signals are electrically conditioned (in terms of current, voltage and frequency) by the switch driver circuit (11) to open and close different combination of switches. The power management circuit (16) allows to power up the main processing unit and the switch driver circuit (11). The required power can be provided by an external battery or, as shown in FIG. 1, by the solar cells in the same PV module. When (17) and (11) are power by the solar cells, a self-start circuit (15) is required.

When the PV module is exposed to sufficient illumination, at the beginning the switches are not yet powered and they are in a default state (e.g., all open). First, the self-start circuit extracts power from at least one of the reconfigurable photovoltaic blocks and stores the energy in (for example) a capacitor. Once there is sufficient energy stored, the power management circuit will power the main processing unit and the switch driver, which in turn will allow to control the state of the switches in (12). While the module is in open circuit (i.e. no power converter (18) connected) the system remains in a stand-by mode where the states of the switches in the matrix remain unchanged and (11) and (17) continue to be powered by at least one reconfigurable block of cells (or a battery in case there is no self-start circuit).

Eventually, a power converter is connected to the output of the PV module (i.e., the left-and right-most terminals in FIG. 2) and this allows power to flow to a load (19) (which can also be the mains electrical grid). As power starts flowing to the grid, the power management circuit (16) disconnects the self-start circuit from the blocks of cells and starts to take power from the power converter (18). In the transition between one power source to another, the energy required by (16) is provided by the abovementioned capacitor. Once the reconfigurable blocks of cells are released from the self-start circuit and the system (i.e. (16) and (11)) is powered by (18), the main processing unit (17) starts to read the current sensors (14) and processes the measurements with an algorithm that determines with is the best combination of open and closed switches.

Now the reconfigurable module enters a new state in which every a certain interval of time (e.g. 1 minute) the current of the reconfigurable blocks are measured, the algorithm implemented in (17) decides the best configuration and then (17) and (11) update the open/closed state of each of the switches in (12). In the meanwhile, the power converter (18) continues to extract power from the positive and negative terminals of the module and delivers it to the load (19).

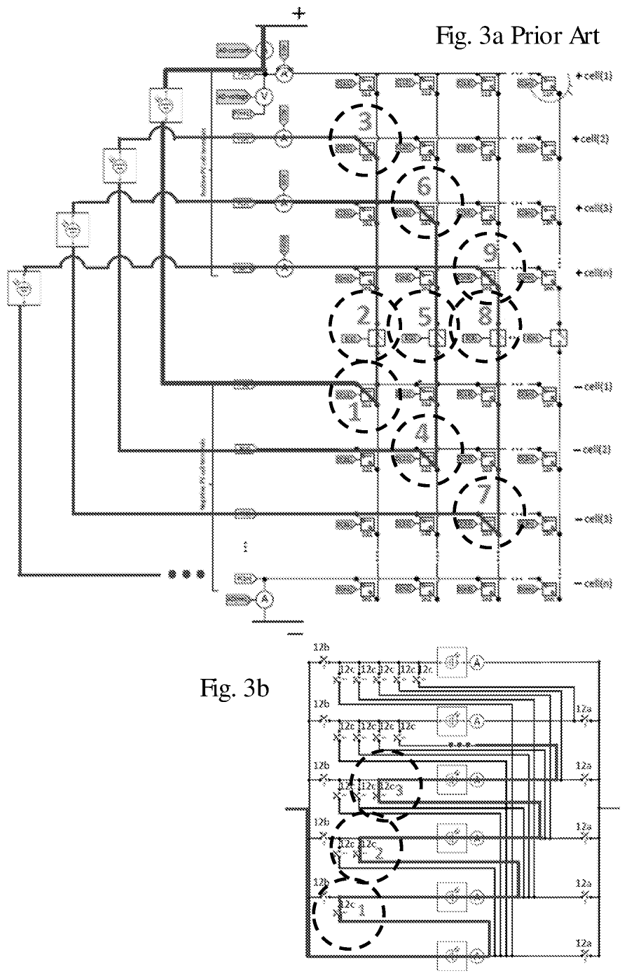

FIGS. 3a-b show a comparison between a prior art layout and the present layout. FIG. 3a relates to the switching matrix disclosed in WO 2019/143242 A1. The switching network comprising a plurality of switchable bypass elements. It covers modules with “switchable bypass elements” and it is explained that a switchable bypass elements is a combination of at least one bypass elements (also known as bypass diode or smart bypass diode as shown in FIG. 1(b) thereof) and one or more switches. These switches can only be used connect or disconnect the bypass element from the PV cell but they cannot be used to connect or disconnect one PV cell from another. Page 6, line 23-31 mentions that “In a second aspect the present invention relates to a method of operating a PV-module comprising n*m cells, and a switching network comprising a plurality of switchable bypass elements, a current or voltage sensor per cell, wherein each PV-cell is individually connected by electrical connections to and controlled by the switching network, comprising receiving for at least two cells a cell current, and a cell voltage, and connecting or disconnecting a switchable bypass element”. In FIG. 3a these are represented as switches, for the sake of comparing topologies. The scalability of matrix proposed in WO 2019/143242 A1 is considered to be conditioned by the limitations of the technology that exists today (and in the foreseeable future). These limitations have to do with the physical properties of the semiconductor materials that are used to make the switches. The approach in the present patent application is less general. It has as main advantages:
1) The number of switches required for the prior art solution increases with four times the second power of the number of solar cells (or groups of cells) in the module, plus two times the number (4*n ²). Instead, the number of switches required in the present case, only increases quadratically (with the second power) with the number of cells (or groups of cells)(0.5*n²). As a consequence, with the same number of switches, the present approach has a higher reconfiguration ability, and thus in principle a higher output power. Also in the present case a more robust layout is provided. All the switches referred to as 12b and 12a can be implemented with only one single transistor. These switches have half of the resistivity compared to the prior art matrix.
2) Under uniform illumination, a reconfigurable module will typically always aim to connect all the cells (or groups of cells) in series to minimize losses. Under such a condition, it is found crucial to minimize the number of switches in the path of the electrical current, such as to reduce heat dissipation. As shown in the FIGS. 3a,b, in the prior art approach 3 switches per cell are required (a total of 9), while in the present approach only 1 switch per cell is required (a total of
3). This reduces to one third the losses under uniform illumination conditions.

1. A cell-level power managed PV-module comprising a multitude of individual PV-cells (i,j) located at a front side of the module, in an array of n*m cells, i∈[2;n], and j∈[2;m], and a junction box comprising
a switch driver circuit adapted to provide individual input to and driving a switching matrix,
the switching matrix adapted to electrically reconnect at least one PV-cell, wherein each block comprises at least one PV-cell, and adapted to receive input from the at least one PV-cells,
at least one sensor per block of PV-cells adapted to receive input from the at least one PV-cell,
a power management circuit adapted to receive input from the at least one PV-cell,
a power converter adapted to provide load, and adapted to receive input from the at least one PV-cell,
a main processing unit the main processing unit adapted to receive input from sensors, adapted to receive input from the power management circuit, adapted to provide input to the switch driver circuit, adapted to provide input to the power management circuit, and adapted to provide input to the power converter, comprising at least one switch per block of PV-cells for reconnecting or disconnecting said block of PV-cells at a positive side of the block of cells and at least one switch at a negative side of the block of cells,
wherein in a row of n PV-cells each PV-cell ∈[1,n−1] comprises one first switch either a positive or negative side of a PV-cell, each first switch connecting or disconnecting to a positive or negative load respectively, and in a row of n PV-cells each PV-cell ∈[2,n] comprises n second switches at the other side of a PV-cell, each second switch either connecting or disconnecting to the other load respectively, or each second switch connecting or disconnecting to an opposite side of an n-1^{th} to 1^{st} PV-cell respectively.

2. The cell-level power managed PV-module according to claim 1, wherein the switching matrix comprises electrically controllable switches.

3. The cell-level power managed PV-module according to claim 1, wherein the junction box is located at a back side of the module and is centrally placed.

4. The cell-level power managed PV-module according to claim 1, comprising at least one switch per block of PV-cells for reconnecting or disconnecting said block of PV-cells at a positive side of the block of cells and at least one switch at a negative side of the block of cells at each cell, apart from a first cell in a block.

5. The cell-level power managed PV-module according, to claim 1, wherein the junction box is selected from an integrated circuit and a PCB.

6. The cell-level power managed PV-module according to claim 1, comprising at least one sensor per PV-cell.

7. The cell-level power managed PV-module according to claim 1, wherein each PV-cell is individually connected by electrical connections to the junction box and controlled by the main processing unit, such that an electrical configuration of PV-cells and the junction box is provided, wherein an electrical operation topology is adaptable by said switching network.

8. The cell-level power managed PV-module according to claim 1, wherein the PV-cell is selected from conventional homo-junction and heterojunction solar cells, mono-facial and bi-facial solar cells, n-type and p-type mono-crystalline Si, micro-crystalline Si bulk, front contacted solar cells, back contacted solar cells, front and rear junction solar cells, and interdigitated back contacted solar cells, and combinations thereof.

9. The cell-level power managed PV-module according to claim 1, wherein the junction box is selected from being located on a back of the PV-module, from being located on the edge of the PV-module, and from being incorporated in the PV-module.

10. The cell-level power managed PV-module according to claim 1, wherein the junction box comprises a printed circuit board provided with a power circuit.

11. The cell-level power managed PV-module according to claim 1, wherein the main processing unit comprises at least one of a clock, a ground, a Vcc, an AD current, an AD-voltage, and a temperature sensor.

12. The cell-level power managed PV-module according to claim 1, comprising a communication circuit.

13. The cell-level power managed PV-module according to claim 1, comprising embedded software for operating the module.

14. A photo-voltaic system comprising a cell-level power managed PV-module according to claim 1, the PV-module comprising
a multitude of individual PV-cells (i,j) located at a front side of the module, in an array of n*m cells, i∈[2;n], and j∈[2;m], and a junction box comprising
a switch driver circuit adapted to provide individual input to and driving a switching matrix,
the switching matrix adapted to electrically reconnect at least one PV-cell, wherein each block comprises at least one PV-cell, and adapted to receive input from the at least one PV-cells,
at least one sensor per block of PV-cells adapted to receive input from the at least one PV-cell,
a power management circuit adapted to receive input from the at least one PV-cell, a power converter, adapted to provide load, and adapted to receive input from the at least one PV-cell,
a main processing unit, the main processing unit adapted to receive input from sensors. adapted to receive input from the power management circuit adapted to provide input to the switch driver circuit, adapted to provide input to the power management circuit, and adapted to provide input to the power converter,
comprising at least one switch per block of RV-cells for reconnecting or disconnecting said block of PV-cells at a positive side of the block of cells and at least one switch at a negative side of the block of cells.
wherein in a row of n PV-cells each PV-cell ∈[1, n-1] comprises one first switch at either a positive or negative side of a PV-cell each first switch connecting or disconnecting to a positive or negative load respectively, and in a row of n PV-cells each PV-cell ∈[2,n] comprises n second switches at the other side of a PV-cell. each second switch either connecting or disconnecting to the other load respectively, or each second switch connecting or disconnecting to an opposite side of an n-1^{th} to 1^{st} PV-cell respectively.
wherein the system is selected from building integrated photovoltaics, vehicle integrated photovoltaics, and urban photovoltaic systems.

15. A method of operating a cell-level power managed PV-module according to claim 1, the PV-module comprising n*m cells, and a switching network comprising a plurality of switches, a processor for controlling the switches, a sensor per cell, wherein each PV-cell is individually connected by electrical connections to and controlled by the switching network, comprising receiving for at least two cells sensor output per cell, and connecting or disconnecting a switch.

16. The method according to claim 15, wherein a cell temperature is measured.

17. The method according to claim 15, wherein an output power of at least two cells is measured.

18. The method according to claim 15, wherein 2⁶-2²⁰ PV modules are maintained and operated.

19. A junction box for operating the cell-level power managed PV-module according to claim 1 comprising a switch driver circuit adapted to provide individual input to and driving a switching matrix,
the switching matrix adapted to electrically reconnect at least one PV-cell, wherein each block comprises at least one PV-cell, and adapted to receive input from the at least one PV-cells,
at least one sensor per block of PV-cells adapted to receive input from the at least one PV-cell,
a power management circuit adapted to receive input from the at least one PV-cell and self-start circuit,
a power converter, adapted to provide load, and adapted to receive input from the at least one PV-cell,
a main processing unit, the main processing unit adapted to receive input from sensors, adapted to receive input from the power management circuit, adapted to provide input to the switch driver circuit, adapted to provide input to the power management circuit, and adapted to provide input to the power converter, comprising at least one switch per block of PV-cells for reconnecting or disconnecting said block of PV-cells at a positive side of the block of cells and at least one switch at a negative side of the block of cells.

20. A computer program for operating the cell-level power managed PV-module according to claim 1, the PV-module comprising a multitude of individual PV-cells (i,j) located at a front side of the module, in an array of n*m cells, i∈[2;n], and j∈[2:m]. and a junction box comprising
a switch driver circuit adapted to provide individual input to and driving a switching matrix,
the switching matrix adapted to electrically reconnect at least one PV-cell, wherein each block comprises at least one PV-cell and adapted to receive input from the at least one PV-cells,
at least one sensor per block of PV-cells adapted to receive input from the at least one PV cell,
a power management circuit adapted to receive input from the at least one PV-cell, a power converter, adapted to provide load, and adapted to receive input from the at least one PV-cell,
a main processing unit, the main processing unit adapted to receive input from sensors, adapted to receive input from the power management circuit, adapted to provide input to the switch driver circuit, adapted to provide input to the power management circuit, and adapted to provide input to the power converter,
comprising at least one switch per block of PV-cells for reconnecting or disconnecting said block of PV-cells at a positive side of the block of cells and at least one switch at a negative side of the block of cells,
wherein in a row of n PV-cells each PV-cell ∈[1,n−1] comprises one first switch at either a positive or negative side of a PV-cell, each first switch connecting disconnecting to a positive or negative load respectively and in a row of n PV-cells each PV-cell ∈[2,n] comprises n second switches at the other side of a PV-cell, each second switch either connecting or disconnecting to the other load respectively, or each second switch connecting or disconnecting to an opposite side of an n-1^{th} to 1^{st} PV-cell respectively,
the computer program comprising instructions, the instructions causing the computer to carry out the following steps:
receiving input from at least one sensor,
receiving input from the power management circuit,
providing input to the switch driver circuit,
providing input to the power management circuit, and providing input to the power converter.
